(19) United States
(12) Patent Application Publication
(10) Pub. No.: US 2008/0023218 A1
(43) Pub. Date: Jan. 31, 2008

(54) Electrolytic plating method

(76) Inventors: Keisuke Nishu, Kanagawa (JP); Morio Iijima, Kanagawa (JP); Naomi Ando, Kanagawa (JP)

Correspondence Address: John L. Cordani;Carmody & Torrance LLP, P.O. Box 1110, 50 Leavenworth Street, Waterbury, CT, 06721-1110, US

(21) Appl. No.: 11/726,992

(22) Filed: Mar. 23, 2007

(30) Foreign Application Priority Data
Jul. 28, 2006 (JP) 2006-205665

(51) Int. Cl. H05K 1/09; C25D 3/38; H01L 23/00

(52) U.S. Cl. 174/257; 205/291; 428/577

(57) ABSTRACT

A novel electrolytic plating method suitable for filling non-through holes with metal is disclosed. The electrolytic plating method uses a plating solution containing additives such as a surfactant, a brightening agent and a smoothing agent and includes pulse plating for controlling adsorption and desorption of tie additives on the surface and in the non-through holes of substrate and subsequent DC plating for filling up the non-through holes with metal.

### FIELD OF THE INVENTION

This invention relates to a novel electrolytic plating method for filling up non-through holes. The method is applicable, for example, to printed circuit boards and semiconductor wafers used in electronic devices or the like.

### BACKGROUND OF THE INVENTION

To meet the recent demand for higher function and downsizing of electronic devices, a technology to fabricate printed circuit boards for high dense assembly is required as well as downsizing of electronic parts such as semiconductors and chip parts. An example of such printed circuit boards is build-up printed circuit boards wherein layers are successfully stacked after the circuit is formed on each layer and are electrically connected through blind via holes (this type of holes may hereinafter be referred to as “non-through holes” in a broad sense, including a blind via hole). In this connection, for the purpose of increasing the density of circuits and assembled parts by mounting on the blind via holes in addition to improving the reliability of interlayer electric connection, there has been proposed a method of filling the blind via holes with metal and been being applied to practical use.

As such a method of filling non-through holes with metal, an electrolytic plating method is considered to be very promising in point of production efficiency and electric properties of metal as a circuit material, and various plating methods and compositions of plating solution have heretofore been proposed (JP 2003-55800A, JP 2003-183879A, JP 2003-183883A, and JP 2003-213489A).

For filling up non-through holes by electrolytic plating it is necessary to make control so that the growth rate of plating is higher at the inside of hole than at the mouth of hole. However, in direct current (DC) plating, as the deposition rate of plating depends on only the distance between a substrate to be plated and a counter electrode based on the shape of substrate, the deposition rate of plating at the mouth of hole and that at the inside of hole cannot be controlled electrically (in terms of the quantity of electricity) by a preset electric current. Therefore it is difficult to fill the inside of non-through hole completely with plated metal without leaving any void or recess within the hole. On the other hand, in the case of pulse plating, it is basically possible to control the deposition rate of plating electrically both at the mouth and at the inside of non-through hole, but strict control of plating condition is required for filling the inside of hole with plated metal. Besides, the plated surface by pulse plating usually becomes rough and uneven, which affects the formation of circuits and the assembly of parts. Further, in JP 2002-164656A there is proposed an electrolytic plating method as a combination of pulse plating with DC plating. In this method, however, DC plating is used only for the purpose of smoothing the uneven surface by pulse plating and the filling of plated metal into non-through holes entirely depends on the properties of pulse plating.

For filling up blind via holes on printed circuit boards or semiconductor wafers, copper sulfate plating is generally used. According to the conventional technologies related to such copper sulfate plating, in order to attain the filling of plated metal into blind via holes, it is necessary that electrolytic plating is carried out at a low current density (usually the maximum of 2 A/dm²) with using a plating solution of high metal concentration (usually 200 g/L or more as copper sulfate pentahydrate). Not only this is insufficient in point of productivity, but also it is difficult to simultaneously attain the satisfactory covering of plating within through holes (this type of holes, including the through holes in question, may hereinafter be referred to as “through holes” in a broad sense) in the case of printed circuit boards with both through holes and non-through holes coexisting. More particularly, in case of filling up non-through holes in accordance with conventional electrolytic plating methods, the composition of plating solution and the plating condition actually applicable are extremely limited.

### OBJECT OF THE INVENTION

This invention has been accomplished in view of the above-mentioned point. It is an object of this invention to provide an electrolytic plating method which enables efficiently and consistently to attain excellent filling performance of plated metal into non-through holes on the substrate to be plated and excellent smoothness of plated surface under various plating condition and various composition of plating solution and further enables to achieve satisfactory covering of plating on the surface of substrate and within through holes.

### SUMMARY OF THE INVENTION

This invention resides in an electrolytic plating method using a plating solution containing additives such as surfactants, brightening agents and smoothing agents, characterized by including the process comprised of a pulse plating step to control adsorption and desorption of the additives on the surface of substrate and within the non-through hole and a subsequent DC plating step to fill up the inside of non-through hole with plated metal.

### DETAILED DESCRIPTION OF THE INVENTION

According to this invention, in the pulse plating step, components having an function of accelerating the deposition of plating (hereinafter referred to as an “accelerator”) are adsorbed and concentrated efficiently and selectively within non-through holes and through holes (both or one of the holes may hereinafter be referred to as merely “holes”) and at the same time the concentration of accelerators is controlled so as to be lower on the surface of substrate than in the holes, then the deposition rate of the next DC plating is controlled as higher in the holes than on the surface of substrate to be plated, which can ensure filling up the inside of non-through hole completely with highly smooth plating and at the same time attaining the satisfactory covering within the through hole.

In this invention, to control the adsorption of accelerators on the surface of substrate to be plated and within the holes, there can be allowed extremely high selectivity of condition in choosing the composition of plating solution (e.g. metal concentration), the current density of pulse plating and DC plating, and the thickness balance between pulse plating and DC plating according to the shape (e.g. diameter, depth) of non-through hole and through hole and to the requirement for covering of plating within the holes and on the surface of substrate. As a result, filling in non-through holes by electrolytic plating can be affected efficiently and consistently.

In this invention, the accelerator to be added into the plating solution indicates any of chemical components at large which can accelerate the deposition rate of plating by electrochemical dispolarizing effect, generally called as a brightening agent or an accelerator. In the invention, one or some of the accelerators can be selected as required.

For example, in the case of filling up the blind via holes on printed circuit board or semiconductor wafer in accordance with the method of this invention, copper sulfate plating is generally used. In the case, the accelerators used should be organic sulfur components including the structure such as SO₃—, —S—, —S—S—, and ═S in the molecule, and the components including nitrogen besides carbon, oxygen and hydrogen in the molecule and/or its metal salt are preferably used.

Assuming that electrolysis wherein the substrate to be plated is a cathode is “forward plating” and electrolysis wherein the substrate is an anode is “reverse plating”, the accelerators are adsorbed onto the substrate by forward plating but be desorbed from the substrate by reverse plating. Here the surface of substrate permits more easy flow of electric current than the inside of non-through hole and through hole, so that the accelerators are more easily desorbed from the surface. Thus, by pulse plating with repeating forward plating and short reverse plating, it is possible to decrease the accelerators adsorbed on the surface of substrate and increase them in the holes. As a result, in the next DC plating, the deposition rate becomes higher within the non-through hole than on the surface of substrate, which ensures filling up the non-through holes with metal deposit.

Also in the through hole, since the accelerators are adsorbed and concentrated in the hole, especially the hole having a higher aspect ratio, by pulse plating, the preliminary pulse plating realizes higher deposition rate of the next DC plating to achieve a high uniform deposition than mere DC plating with no preliminary pulse plating.

In pulse plating, if it is defined that the current density of forward plating is “forward current density” (hereinafter may be referred to as “I_{F}”), the current density of reverse plating is “reverse current density” (hereinafter may be referred to as “I_{R}”), the current density can be set arbitrarily so as to be the I_{R}/I_{F} ratio >1, preferably I_{F}=0.1˜10 A/dm², I_{R}=0.1˜200 A/dm², I_{R}/I_{F}=1˜20, more preferably I_{F}=0.5˜3 A/dm², I_{R}=1˜30 A/dm₂, I_{R}/I_{F}=2˜10.

The time of forward plating and that of reverse plating (designated “T_{F}” and “T_{R}” respectively) can be selected arbitrarily so as to be t_{F}>t_{R} and (I_{F}×t_{F}−I_{R}×t_{R})/(t_{F}+t_{R})>0, preferably t_{F}=1˜100 msec, t_{R}=0.1˜5 msec, more preferably t_{F}=10˜50 msec, t_{R}=0.5˜3 msec.

The amount of accelerators adsorbed and concentrated within the holes on/in the substrate varies depending on how the pulse current is easy to flow. The lower the conductivity of the hole wall becomes and hence the smaller the thickness of deposit by pulse plating becomes, the larger can be made the amount of accelerator adsorbed in the hole.

The maximum thickness of pulse plating (Tp in μm) required for filling non-through holes by the next DC plating can be empirically by the following equation:

T_{P}/R_{H}=L−0.1 log R_{H}
R_{H}: a diameter of the mouth of non-through hole (unit: μm)
L: a constant determined by the current density of DC plating, plating thickness on the surface of substrate, and the composition of plating solution used.
   In the equation above, L is 0.5 or less as long as it is possible to fill a non-through hole by the method of the invention. The value of L becomes lower as the DC density is larger, the thickness of plating on the surface of substrate is smaller, and the metal concentration in the plating solution used is lower. In the case that L exceeds 0.5, pulse plating is not necessary to control the accelerator concentration in a non-through hole, which indicates the possibility of he non-through hole being filled up by only DC plating. In this case, it is necessary to choose the condition such as plating at an extremely low current density, making the plating thickness very large, or increasing the metal concentration of plating solution.

On the other hand, the equation indicates that, in some condition of L, there exists a diameter of the mouth of non-through hole able to fill by only pulse plating without requiring the next DC plating, or a diameter of hole unable to fill by the next DC plating even if the thickness of pulse plating is minimized. According to the equation above, as the diameter at the mouth of non-through hole becomes larger, the maximum thickness of pulse plating becomes larger and opposing the ratio of pulse plating thickness to the diameter of non-through hole becomes lower both of which enable to fill the non-through hole by the next DC plating. Accordingly, unless the ratio of the pulse plating thickness to the diameter at the mouth of non-through hole is smaller, it becomes difficult to fill up the hole with larger diameter by the method of the invention. For example, in the case of L=0.3, it is impossible to fill up non-through holes with a diameter larger than 1 mm at the mouth by the plating method in the invention.

For example, in case of filling up blind via holes on a printed circuit board by copper sulfate plating, it is required that the plating thickness on the surface should be generally 25 μm or less. Here to fill up a normal blind via hole with 100 μm of diameter at the mouth of hole by the method in this invention, the maximum thickness of pulse plating is approximately 15 μm, and preferably less than 5 μm.

When the substrate is partially or entirely a dielectric or a semi-conductive material, a conductive layer (hereinafter may referred to as a conductive underlayer) is preliminarily formed as an underlayer for electrolytic plating by a well-known method such as electroless plating, direct plating, or vapor deposition. By the same reason above, it is preferable that the conductivity of the conductive underlayer is not extremely high and hence it is preferable that the thickness of the conductive underlayer is as small as possible insofar as the next DC plating can work.

In blind via holes on a printed circuit board in which the hole wall is usually dielectric, the thickness of the conductive layer formed as an underlayer for electrolytic plating is much smaller than that of copper circuit formed beforehand on the surface of the printed circuit board, so that accelerators in the plating solution can be efficiently adsorbed and concentrated onto the surface of hole wall by pulse plating. As a result, in the next DC plating, the deposition rate of plating is high on the side wall of hole where the electric current is difficult to flow, especially at the bottom end of the hole wall, and the inside of the hole can be filled up from the bottom end and the side wall. Thus, the hole can be filled up completely without any void formed inside the hole.

This is also the case with applying the method to a blind via hole on a semiconductor wafer.

When pulse plating is followed by DC plating, in this invention, DC plating can be done continuously or intermittently with using the same plating solution. More particularly, in plating equipment wherein the substrate is fixed, DC plating can be subsequently done to pulse plating using the same rectifier. In plating equipment wherein the substrate is movable (transferred by a conveyor), a pulse rectifier and a DC rectifier may be disposed in the early stages and the rear stages of the plating process, so as respectively to achieve the preset target thickness of plating. The invention can be applied to both fixed and movable types of any conventional plating equipment.

The current density of DC plating can be set arbitrarily. In case of copper sulfate plating, it is 0.1 to 20 A/dm², preferably 0.1 to 5 A/dm². When the current density is lower than 0.1 A/dm², long time is necessary for plating, which is insufficient. If the current density is higher than 20 A/dm², not only the filling performance of plating is deteriorated but also burnt deposit is apt to occur. Thus such high current density is inappropriate.

In each of the above pulse plating and DC plating, single conditions may be combined together or respective single and/or some conditions may be combined together. Further, plating may be performed continuously, or an idle time may be set between the plating processes.

In case of filling up non-through holes by copper sulfate plating, the invention can be widely applied to various composition of plating solution, i.e. copper plating solutions usually used in electrolytic plating which contain copper sulfate, sulfuric acid and chloride ion.

Covering of plating generally depends on the composition of plating solution. For example, a plating solution at low copper concentration (e.g. 100 g/L or less as copper sulfate pentahydrate) performs high uniformity of plating but insufficient filling of plating into non-through holes. Contrary, a plating solution at high copper concentration (e.g. 200 g/L or more as copper sulfate pentahydrate) is suitable for filling up non-through holes with plating but inferior in uniformity of plating on the surface of substrate and inside through holes. In the invention, however, since the fill performance of plating into non-through holes can be controlled by the condition of pulse plating, the composition of plating solution can be selected arbitrarily base on the requirement for covering of the next DC plating.

In the invention, either a soluble or an insoluble electrode can be used as a counter electrode relative to a substrate, but by using an insoluble electrode a good fill performance of plating can be consistently obtained in wider condition of plating and plating solution. This is presumed to be because such byproducts as resulting from the reaction between additives in the plating solution and the electrode are not formed and therefore have no bad influence on adsorption of accelerators in pulse plating and on the activity of the accelerators in DC plating.

In general, the deposit of pulse plating has semi-bright or mat surface with small concaves and convexes. In the invention, however, it is possible to obtain a bright and smooth surface of plating because the thickness of pulse plating is small and the surface or the greater part of metal electrolytically plated is formed by DC plating.

By the electrolytic plating method of the invention, the inside of non-through holes can be filled with metal completely and efficiently without forming any void. Especially, even in plating with using the plating solution at low metal concentration or in plating at high current density both in which, it is possible to attain a satisfactory fill performance into the non-through holes.

Although copper sulfate plating has mainly described above as an example, also in the case of other metals, it is possible to fill up non-through holes consistently and afford a smooth surface by the electrolytic plating method of the invention. As long as the object of the invention can be achieved, there is no special limitation in selecting the metal to be plated and the composition of plating solution. Any of them used in conventional electrolytic plating can be used.

The invention will be described in detail hereunder by way of working Examples thereof, but the following Examples are mere illustrations and not limitations of the invention.

In all of the following Examples, there were used as a substrate printed circuit boards having blind via holes each 100 μm in diameter at the mouth and 70 μm in depth including the thickness of surface copper foil. The substrates were plated by pulse plating and sequent DC plating with using the same plating solution in the same tank as those used in the pulse plating.

### EXAMPLE 1

### Influence of Pulse Plating on the Fill Performance of Plating in Non-Through Holes

| | |
|---|---|
| Composition of plating solution | |
| Copper sulfate pentahydrate | 80 g/L |
| Sulfuric acid | 210 g/L |
| Chloride ion | 60 mg/L |
| Polyethylene glycol | 800 mg/L |
| SPS (sodium bis-3-sulfopropyl disulfide) | 5 mg/L |
| Counter electrode | Soluble electrode |
| Condition of pulse plating | |
| Current density | 1.0 A/dm² |
| I_{R}/I_{F} ratio | 3/1 |
| Forward current time | 20 msec |
| Reverse current time | 1 msec |
| Plating time | 0~112 min |
| Condition of DC plating | |
| Current density | 1.0 A/dm² |
| Plating time | 0~112 min |
| Total plating thickness | 25 μm |

FIG. 1 shows cross sections of blind via holes plated in Example 1. When the total plating thickness on the surface was at 25 μm, it was impossible, by only pulse plating or only DC plating, to fill up the inside of holes, but when pulse plating was followed by DC plating, it was possible to fill up the inside of holes. Besides, the smaller the pulse plating thickness became, the more satisfactory the fill performance became. It is seen that in the method of the invention non-through holes can be filled up even by using such a plating solution of lower metal concentration as that used in this Example.

### EXAMPLE 2

### Influence of Plating Solution Additives on the Fill Performance of Plating in Non-Through Holes

| | |
|---|---|
| Composition of plating solution | |
| Copper sulfate pentahydrate | 150 g/L |
| Sulfuric acid | 100 g/L |
| Chloride ion | 60 mg/L |
| Polyethylene glycol | 0 or 800 mg/L |
| SPS (sodium bis-3-sulfopropyl disulfide) | 0 or 5 mg/L |
| Counter electrode | Soluble electrode |
| Condition of pulse plating | |
| Current density | 2.0 A/dm² |
| I_{R}/I_{F} ratio | 3/1 |
| Forward current time | 20 msec |
| Reverse current time | 1 msec |
| Plating time | 10 min |
| Condition of DC plating | |
| Current density | 2.0 A/dm² |
| Plating time | 46 min |
| Total plating thickness | 25 μm |

FIG. 2 shows cross sections of blind via holes plated in Example 2. Of the plating solution additives, polyethylene glycol is an inhibitor (also called suppressor, wetter, or carrier) and SPS is an accelerator. With a plating solution containing SPS, the blind via holes could be completely filled with plating, but in the absence of SPS it was impossible to fill up the holes.

### EXAMPLE 3

### Influence of Thickness of DC Plating on the Fill Performance of Plating in Non-Through Holes)

| | |
|---|---|
| Composition of plating solution | |
| Copper sulfate pentahydrate | 150 g/L |
| Sulfuric acid | 100 g/L |
| Chloride ion | 60 mg/L |
| Polyethylene glycol | 800 mg/L |
| SPS (sodium bis-3-sulfopropyl disulfide) | 5 mg/L |
| Counter electrode | Insoluble electrode |
| Condition of pulse plating | |
| Current density | 1.0 A/dm² |
| I_{R}/I_{F} ratio | 3/1 |
| Forward current time | 20 msec |
| Reverse current time | 1 msec |
| Plating time | 10 min |
| Condition of DC plating | |
| Current density | 1.0 A/dm² |
| Plating time | 0~90 min |
| Total plating thickness | 0~20 μm |

FIG. 3 shows cross sections of blind via holes plated in Example 3. Since DC plating grows at the bottom edge of the blind via hole, it is seen that the hole can be filled up completely without forming any void in the hole.

### EXAMPLE 4

### Influence of Current Density of DC Plating on the Fill Performance of Plating in Non-Through Holes

| | |
|---|---|
| Composition of plating solution | |
| Copper sulfate pentahydrate | 150 g/L |
| Sulfuric acid | 100 g/L |
| Chloride ion | 60 mg/L |
| Polyethylene glycol | 800 mg/L |
| SPS (sodium bis-3-sulfopropyl disulfide) | 5 mg/L |
| Counter electrode | Insoluble electrode |
| Condition of pulse plating | |
| Current density | 1.0 A/dm² |
| IR/IF ratio | 3/1 |
| Forward current time | 20 msec |
| Reverse current time | 1 msec |
| Plating time | 10 min |
| Condition of DC plating | |
| Current density | 1.0~4.0 A/dm² |
| Plating time | 25~102 min |
| Total plating thickness | 25 μm |

FIG. 4 shows cross sections of blind via holes plated in Example 4. In this Example it was possible to fill up the blind via hole at the current density of the range 1.0 to 4.0 A/dm² in DC plating. That the range of condition permitting fills of non-through holes becomes wider as a result of using the insoluble electrode as a counter electrode and that the method of the invention permits fill of non-through holes even at high current density and is thus an extremely efficient method.

### BRIEF DESCRIPTION OF THE DRAWINGS

FIG. 1 shows cross-sections of blind via holes in a printed circuit board plated in Example 1.

FIG. 2 shows cross-sections of blind via holes in a printed circuit board plated in Example 2.

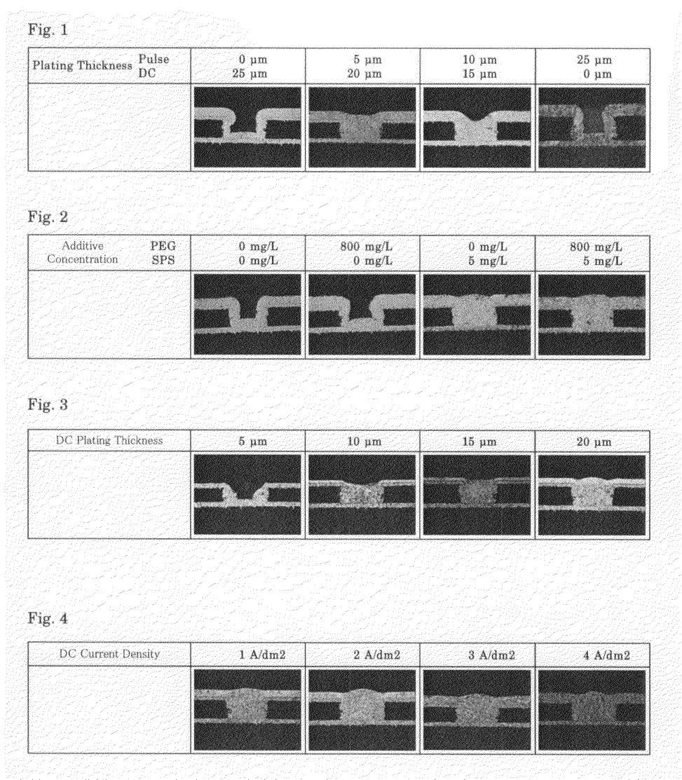

1. An electrolytic plating method using the plating solution containing additives such as surfactants, brightening agents and smoothing agents, characterized by a plating process comprising a pulse plating to control adsorption and desorption of the additives and a subsequent DC plating to fill up non-thorough holes.

2. An electrolytic plating method according to claim 1, wherein the thickness of plating formed by the pulse plating is not larger than 15 μm.

3. An electrolytic plating method according to claim 1, wherein the plating solution contains as an additive at least a component which exhibits the acceleration of metal deposition of plating.

4. An electrolytic plating method according to claim 1, wherein an insoluble electrode is used as a counter electrode relative to the substrate to be plated.

5. An electrolytic plating method according to claim 1, wherein the metal deposited as plating is copper.

6. A printed circuit board having at least one non-through hole electrolytically plated by the method according to claim 1.

7. A semiconductor wafer plated electrolytically by the method described in claim 1.
